(19) United States
(12) Patent Application Publication
(10) Pub. No.: US 2014/0062906 A1
(43) Pub. Date: Mar. 6, 2014

(54) TOUCH SCREENS AND METHODS OF MANUFACTURING THE SAME

(71) Applicant: ELECTRONICS AND TELECOMMUNICATIONS RESEARCH IN, Daejeon (KR)

(72) Inventor: Rae-Man PARK, Daejeon (KR)

(73) Assignee: Electronics and Telecommunications Research Institute, Daejeon (KR)

(21) Appl. No.: 13/709,969

(22) Filed: Dec. 10, 2012

(30) Foreign Application Priority Data
Sep. 6, 2012 (KR) 10-2012-0098928

(51) Int. Cl. G06F 3/041; H01L 21/00

(52) U.S. Cl. CPC G06F 3/041; H01L 21/00
USPC 345/173; 29/622

(57) ABSTRACT

Disclosed are touch screens and methods of manufacturing the same. The touch screen may include a substrate, a first electrode extending in a first direction on the substrate, an interlayer insulating layer disposed on the first electrode, and a second electrode disposed on the interlayer insulating layer and extending in a second direction crossing the first direction. The interlayer insulating layer may have quantum dots that induce a change of a capacitance between the first electrode and the second electrode by a visible light incident on the substrate.

### CROSS-REFERENCE TO RELATED APPLICATIONS

This U.S. non-provisional patent application claims priority under 35 U.S.C. §119 to Korean Patent Application No. 10-2012-0098928, filed on Sep. 6, 2012, the entirety of which is incorporated by reference herein.

### BACKGROUND

The inventive concept relates to touch screens and methods of manufacturing the same and, more particularly, to touch screens sensing a light touch and methods of manufacturing the same.

Recently, a touch screen market is growing rapidly with the development of a smart phone market. The touch screens are input units recognizing a touch of a screen in a display device. The touch screens may be categorized into a resistive type touch screen and a capacitive type touch screen.

The resistive type touch screen may sense a contact resistance between electrodes. The electrodes are spaced apart from each other by a predetermined distance. If the electrodes approach each other by a touch of a finger or a pen, a resistance between the electrodes is reduced. The resistive type touch screen may have a faster response speed and excellent transmittance. The resistive type touch screen may be mainly applied to a personal digital assistant (PDA), a portable multimedia player (PMP), a navigation device, and a headset.

The capacitive type touch screen may sense static electricity of a finger. The static electricity may change a capacitance between electrodes. An insulating layer is disposed between the electrodes. The capacitive type touch screen may easily perform multi-touch and have excellent visibility as compared with the resistive type touch screen.

### SUMMARY

Embodiments of the inventive concept may provide touch screens capable of sensing a light touch and methods of manufacturing the same.

Embodiments of the inventive concept may also provide touch screens capable of improving productivity and methods of manufacturing the same.

In one aspect, a touch screen may include: a substrate; a first electrode extending in a first direction on the substrate; an interlayer insulating layer disposed on the first electrode; and a second electrode disposed on the interlayer insulating layer and extending in a second direction crossing the first direction. The interlayer insulating layer may have quantum dots that induce a change of a capacitance between the first electrode and the second electrode by a visible light incident on the substrate.

In an embodiment, the quantum dots may include silicon nano particles.

In an embodiment, each of the silicon nano particles may have a particle size within a range of about 2 nm to about 7 nm.

In an embodiment, a number density of the silicon nano particles in the interlayer insulating layer may have a range of about 1×10¹⁶ ea/Cm³ to about 1×10¹⁸ ea/cm³.

In an embodiment, the interlayer insulating layer may include a silicon oxide layer or a silicon nitride layer.

In an embodiment, the first electrode and a second electrode may include a transparent metal.

In an embodiment, the transparent metal may include indium-tin oxide (ITO) and/or indium-zinc oxide (IZO).

In an embodiment, the second electrode may include: separation electrodes spaced apart from each other in the second direction on the substrate, the first electrode passing between the separation electrodes, and the separation electrodes separated from the first electrode; and a bridge electrode connected to the separation electrodes and formed on the interlayer insulating layer.

In another aspect, a method of manufacturing a touch screen may include: forming a first electrode on a substrate; forming an interlayer insulating layer having quantum dots on the first electrode; and forming a second electrode on the interlayer insulating layer.

In an embodiment, the interlayer insulating layer may be formed by a plasma enhanced-chemical vapor deposition (PE-CVD) process.

In an embodiment, a silane gas and a nitrogen gas may be used as a source gas and a reaction gas of the PE-CVD process, respectively.

In an embodiment, a mixture ratio of the silane gas to the nitrogen gas may be within a range of about 1:1000 to about 1:4000 in the PE-CVD process.

In an embodiment, a silane gas and an ammonia gas may be used as a source gas and a reaction gas of the PE-CVD process, respectively.

In an embodiment, a mixture ratio of the silane gas to the ammonia gas may be within a range of about 1:1 to about 1:5 in the PE-CVD process.

### BRIEF DESCRIPTION OF THE DRAWINGS

The inventive concept will become more apparent in view of the attached drawings and accompanying detailed description.

FIG. 1 is a plan view illustrating a touch screen according to a first embodiment of the inventive concept;

FIG. 2 is a cross-sectional view taken along a line I-I′ of FIG. 1;

FIG. 3 is a graph illustrating variation of an electrical capacitance induced between a lower electrode and an upper electrode;

FIGS. 4 to 6 are cross-sectional views illustrating a method of manufacturing a touch screen according to a first embodiment of the inventive concept;

FIG. 7 is a schematic diagram illustrating a chemical vapor deposition apparatus for depositing an interlayer insulating layer of FIG. 5;

FIG. 8 is a plan view illustrating a touch screen according to a second embodiment of the inventive concept;

FIG. 9 is a cross-sectional view taken along a line II-IP of FIG. 8; and

FIGS. 10 to 12 are cross-sectional views illustrating a method of manufacturing a touch screen of FIG. 9.

### DETAILED DESCRIPTION OF THE EMBODIMENTS

The inventive concept will now be described more fully hereinafter with reference to the accompanying drawings, in which exemplary embodiments of the inventive concept are shown. The advantages and features of the inventive concept and methods of achieving them will be apparent from the following exemplary embodiments that will be described in more detail with reference to the accompanying drawings. It should be noted, however, that the inventive concept is not limited to the following exemplary embodiments, and may be implemented in various forms. Accordingly, the exemplary embodiments are provided only to disclose the inventive concept and let those skilled in the art know the category of the inventive concept. In the drawings, embodiments of the inventive concept are not limited to the specific examples provided herein and are exaggerated for clarity.

The terminology used herein is for the purpose of describing particular embodiments only and is not intended to limit the invention. As used herein, the singular terms “a,” “an” and “the” are intended to include the plural forms as well, unless the context clearly indicates otherwise. As used herein, the term “and/or” includes any and all combinations of one or more of the associated listed items. It will be understood that when an element is referred to as being “connected” or “coupled” to another element, it may be directly connected or coupled to the other element or intervening elements may be present.

Similarly, it will be understood that when an element such as a layer, region or substrate is referred to as being “on” another element, it can be directly on the other element or intervening elements may be present. In contrast, the term “directly” means that there are no intervening elements. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

Additionally, the embodiment in the detailed description will be described with sectional views as ideal exemplary views of the inventive concept. Accordingly, shapes of the exemplary views may be modified according to manufacturing techniques and/or allowable errors. Therefore, the embodiments of the inventive concept are not limited to the specific shape illustrated in the exemplary views, but may include other shapes that may be created according to manufacturing processes. Areas exemplified in the drawings have general properties, and are used to illustrate specific shapes of elements. Thus, this should not be construed as limited to the scope of the inventive concept.

It will be also understood that although the terms first, second, third etc. may be used herein to describe various elements, these elements should not be limited by these terms. These terms are only used to distinguish one element from another element. Thus, a first element in some embodiments could be termed a second element in other embodiments without departing from the teachings of the present invention. Exemplary embodiments of aspects of the present inventive concept explained and illustrated herein include their complementary counterparts. The same reference numerals or the same reference designators denote the same elements throughout the specification.

Moreover, exemplary embodiments are described herein with reference to cross-sectional illustrations and/or plane illustrations that are idealized exemplary illustrations. Accordingly, variations from the shapes of the illustrations as a result, for example, of manufacturing techniques and/or tolerances, are to be expected. Thus, exemplary embodiments should not be construed as limited to the shapes of regions illustrated herein but are to include deviations in shapes that result, for example, from manufacturing. For example, an etching region illustrated as a rectangle will, typically, have rounded or curved features. Thus, the regions illustrated in the figures are schematic in nature and their shapes are not intended to illustrate the actual shape of a region of a device and are not intended to limit the scope of example embodiments.

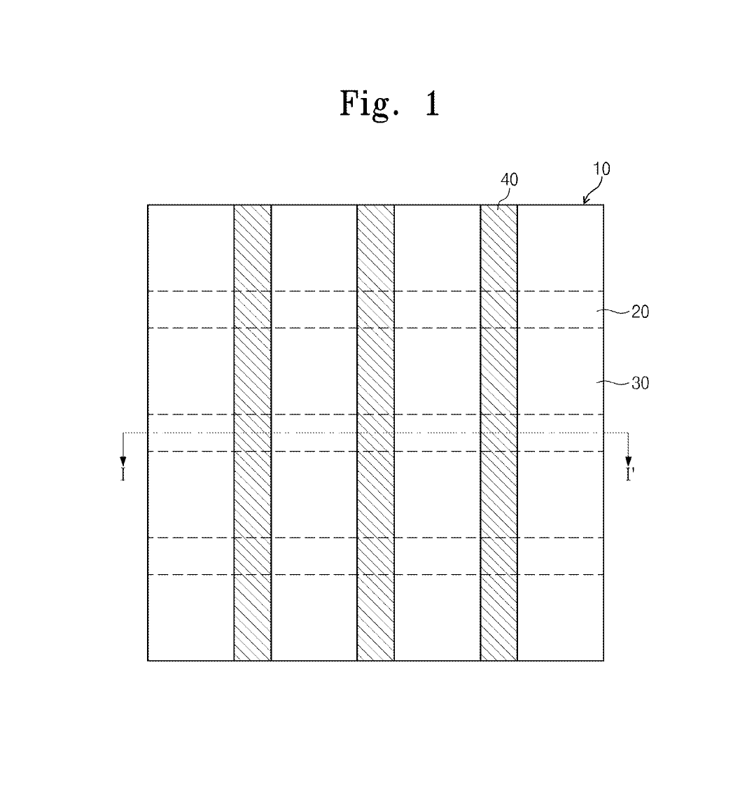

FIG. 1 is a plan view illustrating a touch screen according to a first embodiment of the inventive concept. FIG. 2 is a cross-sectional view taken along a line I-I′ of FIG. 1.

Referring to FIGS. 1 and 2, a touch screen according to a first embodiment may include a substrate 10, a lower electrode 20, and an interlayer insulating layer 30, and an upper electrode 40.

The substrate 10 may include a transparent substrate or a flexible substrate. The transparent substrate may be a glass substrate. The flexible substrate may be a plastic substrate.

The lower electrode 20 and the upper electrode 40 may be transparent electrodes. The transparent electrodes may include indium-tin oxide (ITO) and/or indium-zinc oxide (IZO). The lower electrode 20 may extend in a first direction. The upper electrode 40 may extend in a second direction. The first direction may be different from the second direction.

The interlayer insulating layer 30 covers the substrate 10 and the lower electrode 20. The interlayer insulating layer 30 is disposed between the lower electrode 20 and the upper electrode 40. The interlayer insulating layer 30 may include a dielectric layer such as a silicon oxide layer and/or a silicon nitride layer. The dielectric layer may have a thickness of about 100 nm or more. Generally, the dielectric layer may have dielectric polarization. If first charges are applied to one of the lower and upper electrodes 20 and 40, second charges may be induced in the other of the lower and upper electrodes 20 and 40. The first charge and the second charge have polarities opposite to each other, respectively. Thus, the touch screen according to the first embodiment may be a capacitive type touch screen.

The interlayer insulating layer 30 may have quantum dots 50. The quantum dots 50 may include silicon nano particles. The quantum dots 50 may hardly influence a transmittance of the interlayer insulating layer 30. The silicon nitride layer may have a transmittance of about 80% or more. Each of the quantum dots 50 may have a particle size within a range of about 1 nm to about 10 nm. More particularly, each of the quantum dots 50 may have a particle size within a range of about 2 nm to about 7 nm. The quantum dots 50 may have a number density within a range of about 1×10¹⁶ ea/cm³ to about 1×10¹⁸ ea/cm³ in the interlayer insulating layer 30.

Meanwhile, a visible light may excite valence band electrons of the quantum dots 50. The valence band electrons may momently generate an electric field in the interlayer insulating layer 30. Thus, peripheral electrons may change the capacitance between the lower electrode 20 and the upper electrode 40. In other words, the visible layer may induce the change of the capacitance. The capacitance may be represented as the following equation 1.

Cₜₒₜₐₗ=C_{ref}+C_{nd} [Equation 1]

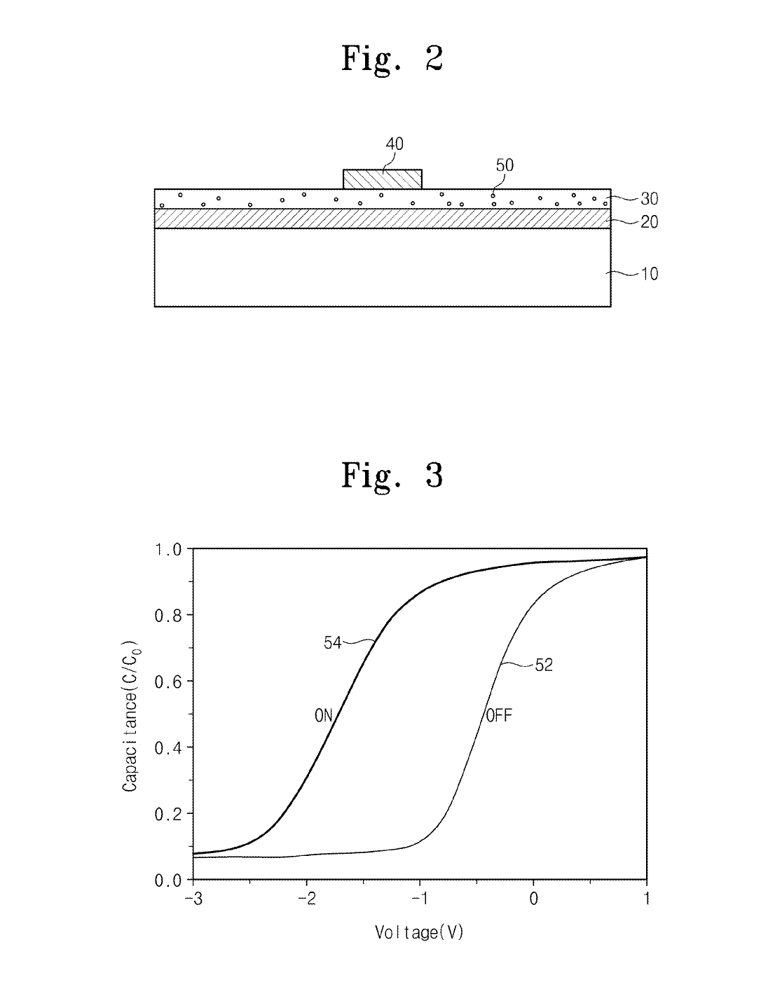

Here, “Cₜₒₜₐₗ” denotes a total capacitance value induced in the interlayer insulating layer 30 between the lower electrode 20 and the upper electrode 40, “C_{ref}” denotes a reference capacitance value of the interlayer insulating layer 30, and “C_{nd}” denotes a light touch capacitance value (or an optical sensing capacitance value). The total capacitance value Cₜₒₜₐₗ may be calculated from a sum of the reference capacitance value C_{ref} and the light touch capacitance value C_{nd}. The capacitance change of the interlayer insulating layer 30 may be described by the graph illustrated in FIG. 3.

FIG. 3 is a graph illustrating variation of an electrical capacitance induced between a lower electrode and an upper electrode.

Referring to FIGS. 2 and 3, the total capacitance value may increase when the visible light is irradiated to the touch screen. A reference numeral “52” represents a capacitance change of the touch screen irradiated with the visible light. A reference numeral “54” represents a capacitance change of the touch screen not irradiated with the visible light. In the graph, a horizontal axis represents a voltage V applied between the lower electrode 20 and the upper electrode 40, and a vertical axis represents a normalized capacitance. The interlayer insulating layer 30 was formed of a silicon nitride layer having a thickness of about 100 nm.

When a voltage of −1V is applied between the lower electrode 20 and the upper electrode 40, the light touch capacitance value was nine or more times greater than the reference capacitance value. A user may directly input an input value to the touch screen with a laser pointer. The laser pointer may emit a monochromatic visible light.

Thus, the touch screen according to the first embodiment may sense the light touch in a capacitive manner.

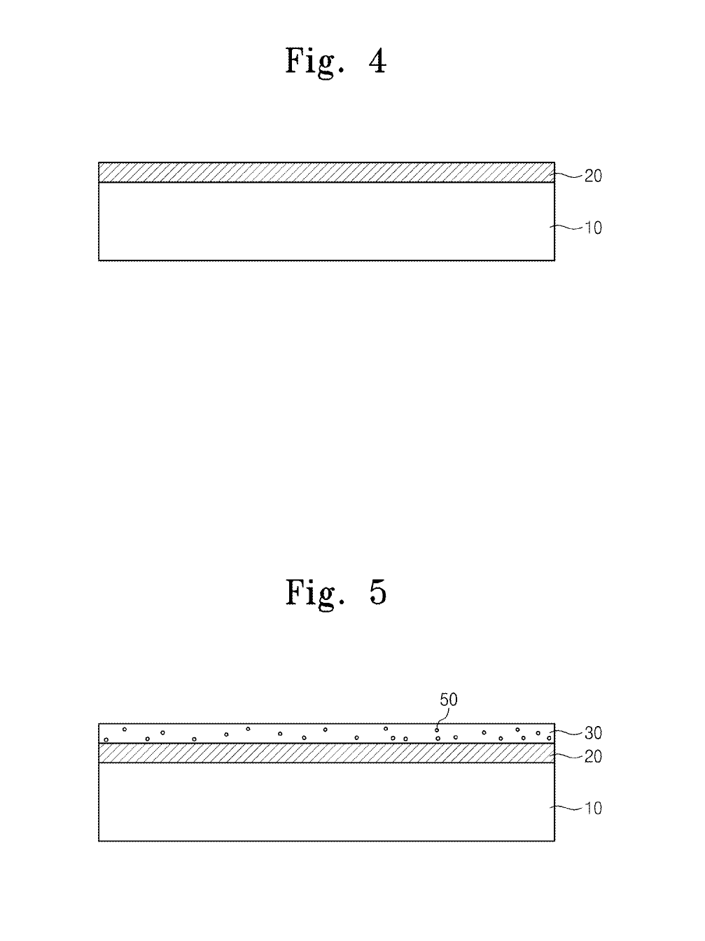

A method of manufacturing the touch screen according to the first embodiment will be described with reference to FIGS. 4 to 6.

FIGS. 4 to 6 are cross-sectional views illustrating a method of manufacturing a touch screen according to a first embodiment of the inventive concept. FIGS. 4 to 6 are cross-sectional views taken along a line I-I′ of FIG. 1. FIG. 7 is a schematic diagram illustrating a chemical vapor deposition apparatus for depositing an interlayer insulating layer of FIG. 5.

Referring to FIGS. 1 and 4, a lower electrode 20 extending in a first direction is formed on a substrate 10. The lower electrode 20 may include ITO and/or IZO. The lower electrode 20 may be formed by a depositing process, a photolithograph process, and an etching process. The depositing process may include a sputtering process.

Referring to FIGS. 1 and 5, an interlayer insulating layer 30 is formed on the lower electrode 20 and the substrate 10. The interlayer insulating layer 30 may be formed by a plasma enhanced-chemical vapor deposition (PE-CVD) process. The PE-CVD process will be described with reference to FIG. 7.

The interlayer insulating layer 30 may be formed by chemical reaction of a source gas and a reaction gas. The source gas may include a silane (SiH₄) gas. The reaction gas may include a nitrogen (N₂) gas or an ammonia (NH₃) gas. The substrate 10 may be supported by a chuck 110. A gas supplying part 200 supplies the source gas and the reaction gas into a chamber 100. A showerhead 120 may mix the source gas and the reaction gas in a plasma state and then jet the mixed gas to the substrate 10.

According to some embodiments of the inventive concept, the silane gas and the nitrogen gas may be supplied into the chamber 100 in the PE-CVD process. At this time, a mixture ratio of the silane gas to the nitrogen gas may be within a range of about 1:1000 to about 1:4000. In this case, the silicon nitride layer may be deposited on the substrate 10 at a growth rate within a range of about 1.3 nm/min to about 1.8 nm/min. At this time, quantum dots 50 may be formed in the silicon nitride layer. Each of the quantum dots 50 may have a particle size within a range of about 2 nm to about 7 nm. The quantum dots 50 may exist in the silicon nitride layer with a number density having a range of about 1×10¹⁶ ea/cm³ to about 1×10¹⁸ ea/cm³. The quantum dots 50 may be silicon nano particles.

According to other embodiments of the inventive concept, the silane gas and the ammonia gas may be supplied into the chamber 100 in the PE-CVD process. At this time, a mixture ratio of the silane gas to the ammonia gas may be within a range of about 1:1 to about 1:5. In this case, the silicon nitride layer may be deposited on the substrate 10 at a growth rate within a range of about 5 nm/min to about 10 nm/min. The quantum dots 50 may be formed in the interlayer insulating layer 30 without an additional thermal annealing process and/or an additional patterning process.

Thus, the manufacturing method of the touch screen according to the first embodiment may improve productivity and production yield.

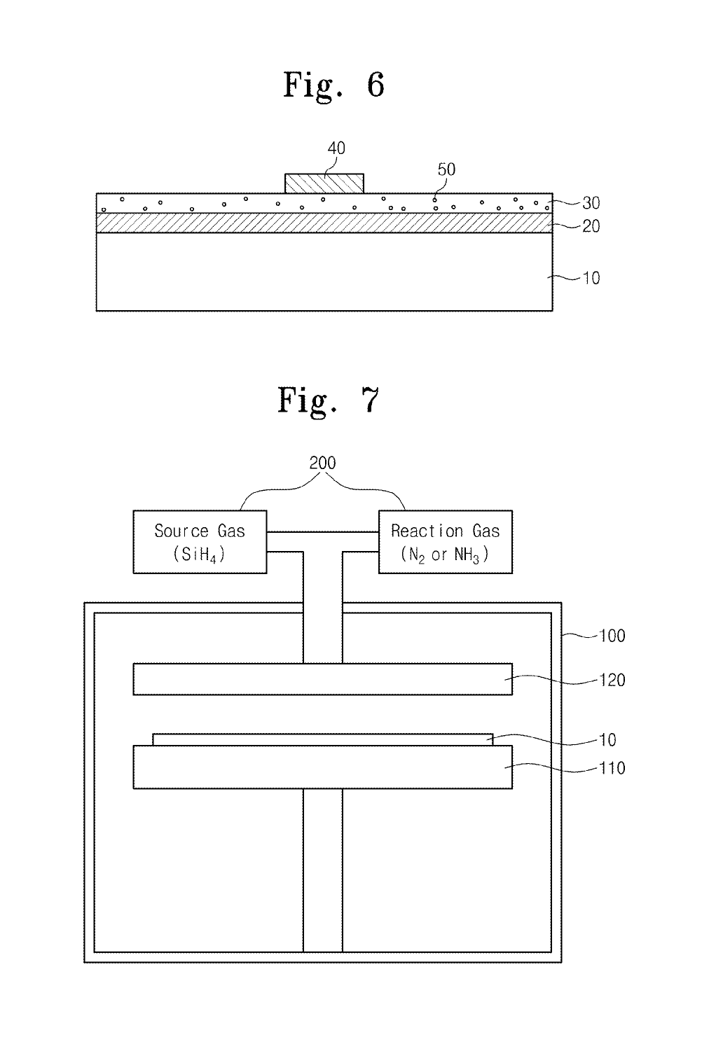

Referring to FIGS. 1 and 6, an upper electrode 40 extending in a second direction is formed on the interlayer insulating layer 30. The upper electrode 40 may be formed by a depositing process, a photolithography process, and an etching process. The upper electrode 40 may include ITO and/or IZO. The depositing process for the upper electrode 40 may include a sputtering process.

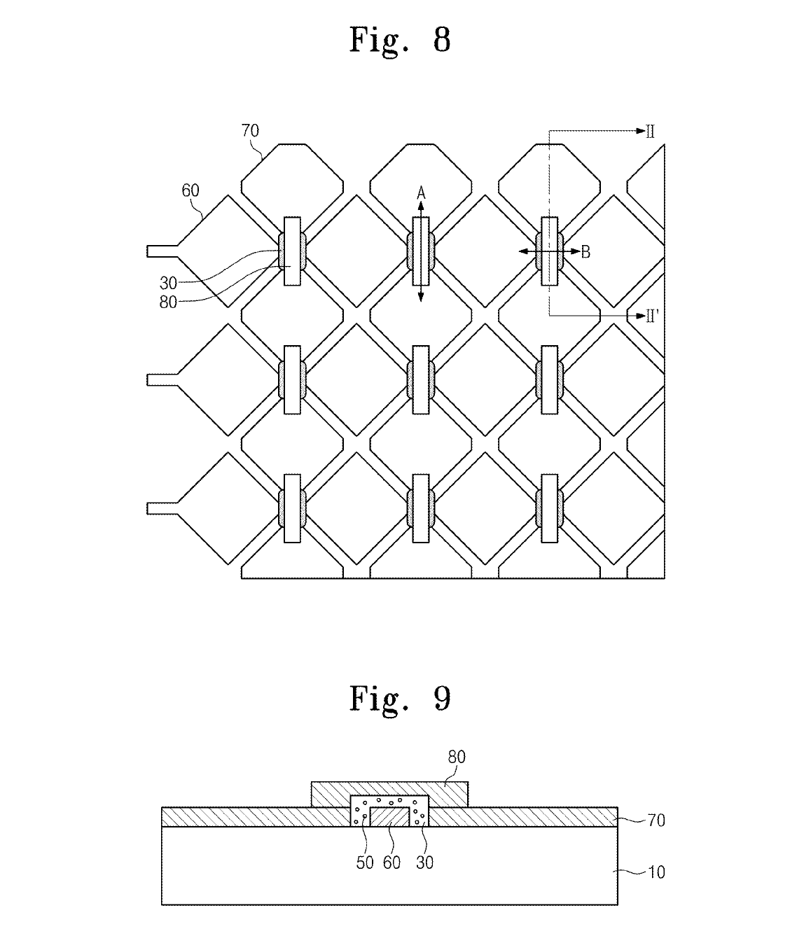

FIG. 8 is a plan view illustrating a touch screen according to a second embodiment of the inventive concept. FIG. 9 is a cross-sectional view taken along a line II-II′ of FIG. 8.

Referring to FIGS. 8 and 9, a touch screen according to a second embodiment may include line electrodes 60, separation electrodes 70, an interlayer insulating layer 30, and bridge electrodes 80.

The line electrodes 60 may extend in a first direction on a substrate 10. Each of the line electrodes 60 may pass between the separation electrodes 70. The line electrodes 60 may transmit a visible light. The line electrodes 60 may include ITO and/or IZO. The line electrodes 60 may correspond to the lower electrode 20 in the first embodiment. The line electrodes 60 and the separation electrodes 70 may be disposed at the same level on the substrate 10.

The separation electrodes 70 may be spaced apart from each other in a second direction. Here, the first direction may be an x-axis direction, and the second direction may be a y-axis direction. The separation electrodes 70 may be spaced apart from the line electrodes 60. The separation electrodes 70 may be disposed on the substrate 10. The separation electrodes 70 may include ITO and/or IZO. The separation electrodes 70 and the bridge electrodes 80 may correspond to the upper electrode 40 in the first embodiment.

The interlayer insulating layer 30 may cover the line electrodes 60 between the separation electrodes 70. The interlayer insulating layer 30 may include a silicon nitride layer or a silicon oxide layer. The interlayer insulating layer 30 have quantum dots 50.

The bridge electrodes 80 may be disposed on the interlayer insulating layer 30 and the separation electrodes 70. The bridge electrodes 80 connect the separation electrodes 70 arranged in the second direction to each other. The bridge electrodes 80 may transmit the visible light. The bridge electrodes 80 may include ITO and/or IZO.

If the visible light is irradiated to the interlayer insulating layer 30, a capacitance between the bridge electrode 80 and the line electrode 60 may be changed. Thus, the touch screen according to the second embodiment may sense the light touch in the capacitive manner.

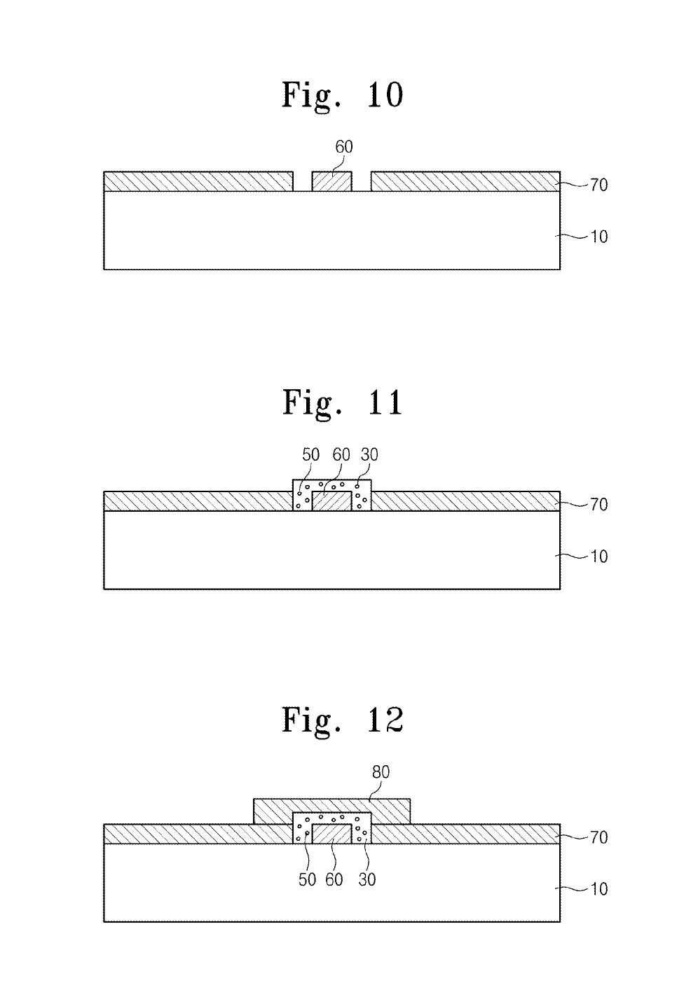

A method of manufacturing the touch screen according to the second embodiment will be described with reference to FIGS. 10 to 12.

FIGS. 10 to 12 are cross-sectional views illustrating a method of manufacturing a touch screen of FIG. 9.

Referring to FIGS. 8 and 10, line electrodes 60 and separation electrodes 70 are formed on a substrate 10. The line electrodes 60 and the separation electrodes 70 may be formed by a sputtering process, a photolithography process, and an etching process. The line electrodes 60 may extend in a first direction on the substrate 10. The separation electrodes 70 may be spaced apart from each other in a second direction different from the first direction.

Referring to FIGS. 7 and 11, an interlayer insulating layer 30 is formed on the line electrodes 60. The interlayer insulating layer 30 may be formed by a depositing process, a lithography process, and an etching process. The depositing process for the interlayer insulating layer 30 may include a PE-CVD process. As described above, the interlayer insulating layer 30 may be formed by chemical reaction of the silane (SiH₄) gas and one of the nitrogen (N₂) gas and the ammonia (NH₃) gas. At this time, quantum dots 50 may be formed in the interlayer insulating layer 30 by the depositing process of the interlayer insulating layer 30 without an additional thermal annealing process.

Thus, the manufacturing method of the touch screen according to the second embodiment may improve productivity and production yield.

Referring to FIGS. 8 and 12, a bridge electrode 80 is formed on the interlayer insulating layer 30 and the separation electrodes 70. The bridge electrode 80 may be formed by a depositing process, a lithography process, and an etching process. The depositing process for the bridge electrode 80 may include a sputtering process.

According to embodiments of the inventive concept, the touch screen may include the quantum dots formed in the interlayer insulating layer between the electrodes. The interlayer insulating layer may include the dielectric layer. The dielectric layer has the dielectric polarization. If first charges are applied to one of the electrodes, second charges may be induced in the other of the electrodes. The first charge and the second charge have polarities opposite to each other, respectively. The touch screen may be driven in the capacitive type manner. The quantum dots may absorb the visible light, so as to change an intensity of the electric field generated between the electrodes. The visible light may induce the change of the capacitance between the electrodes. Thus, the touch screen according to embodiments of the inventive concept may sense the light touch in the capacitive type manner.

Additionally, the interlayer insulating layer may be formed by the PE-CVD process. The quantum dots may be formed simultaneously with the depositing process of the interlayer insulating layer without an additional thermal annealing process and/or an additional depositing process. As a result, the manufacturing method according to embodiments of the inventive concept may improve productivity and production yield.

While the inventive concept has been described with reference to example embodiments, it will be apparent to those skilled in the art that various changes and modifications may be made without departing from the spirit and scope of the inventive concept. Therefore, it should be understood that the above embodiments are not limiting, but illustrative. Thus, the scope of the inventive concept is to be determined by the broadest permissible interpretation of the following claims and their equivalents, and shall not be restricted or limited by the foregoing description.

What is claimed is:

1. A touch screen comprising:
a substrate;
a first electrode extending in a first direction on the substrate;
an interlayer insulating layer disposed on the first electrode; and
a second electrode disposed on the interlayer insulating layer and extending in a second direction crossing the first direction,
wherein the interlayer insulating layer has quantum dots that induce a change of a capacitance between the first electrode and the second electrode by a visible light incident on the substrate.

2. The touch screen of claim 1, wherein the quantum dots include silicon nano particles.

3. The touch screen of claim 2, wherein each of the silicon nano particles has a particle size within a range of about 2 nm to about 7 nm.

4. The touch screen of claim 2, wherein a number density of the silicon nano particles in the interlayer insulating layer has a range of about 1×10¹⁶ ea/cm³ to about 1×10¹⁸ ea/cm³.

5. The touch screen of claim 1, wherein the interlayer insulating layer includes a silicon oxide layer or a silicon nitride layer.

6. The touch screen of claim 1, wherein the first electrode and a second electrode include a transparent metal.

7. The touch screen of claim 6, wherein the transparent metal includes indium-tin oxide (ITO) and/or indium-zinc oxide (IZO).

8. The touch screen of claim 1, wherein the second electrode comprises:
separation electrodes spaced apart from each other in the second direction on the substrate, the first electrode passing between the separation electrodes, and the separation electrodes separated from the first electrode; and
a bridge electrode connected to the separation electrodes and formed on the interlayer insulating layer.

9. A method of manufacturing a touch screen comprising:
forming a first electrode on a substrate;
forming an interlayer insulating layer having quantum dots on the first electrode; and
forming a second electrode on the interlayer insulating layer.

10. The method of claim 9, wherein the interlayer insulating layer is formed by a plasma enhanced-chemical vapor deposition (PE-CVD) process.

11. The method of claim 10, wherein a silane gas and a nitrogen gas are used as a source gas and a reaction gas of the PE-CVD process, respectively.

12. The method of claim 11, wherein a mixture ratio of the silane gas to the nitrogen gas is within a range of about 1:1000 to about 1:4000 in the PE-CVD process.

13. The method of claim 10, wherein a silane gas and an ammonia gas are used as a source gas and a reaction gas of the PE-CVD process, respectively.

14. The method of claim 13, wherein a mixture ratio of the silane gas to the ammonia gas is within a range of about 1:1 to about 1:5 in the PE-CVD process.
